(19) United States
(12) Patent Application Publication
(10) Pub. No.: US 2006/0160365 A1
(43) Pub. Date: Jul. 20, 2006

(54) Water-cooling apparatus for semiconductor thermal processing

(76) Inventor: Cheng-Ming Wang, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 11/034,841

(22) Filed: Jan. 14, 2005

(51) Int. Cl. H01L 21/302

(52) U.S. Cl. 438/715

(57) ABSTRACT

A water-cooling apparatus for semiconductor thermal processing compring two supply pipes and two recycle pipes for respectively connecting to two chambers for performing the semiconductor processing. Each chamber has one set of pipes for supplying and recycling the cooling water in order to adjust the temperature in the chambers and maintain sufficient water pressure and flow, thereby preventing insufficient water pressure, thereby resulting in increased throughput. A water pump is not required in order to increase the water pressure, thereby reducing the maintenance cost.

### BACKGROUND OF THE INVENTION

1. Field of the Invention

The present invention relates to a water-cooling apparatus, and more particularly, to a water-cooling apparatus for semiconductor thermal processing.

2. Description of the Prior Art

In semiconductor processing, the applied technology is a quite complex technology. Each wafer is usually subjected to many processes, such as thin film growth, deposition, lithography, etching, thermal annealing and so on. Therefore, the semiconductor industry requires a lot of money, equipment and advanced technology.

In semiconductor processing, the temperature is a very important issue to affect the processing. The equipment for controlling the temperature, which is the heating and cooling apparatus, occupies an important factor in the semiconductor processing. There are a lot of heating methods, for example, resistive heating, heating coil, or tungsten Halogen Heating lamp. Water is usually used in cooling since it is the most economical and effective way. Therefore, a large amount of water is required for cooling.

Water-cooling is often used in thermal processing, for example, thermal oxidation, thermal flow processing, metal silicidation processing, anneal processing, solidification processing, rapid thermal processing and so on. Taking a rapid thermal processing as an example, the rapid thermal processing chamber 10 mainly comprises an external chamber 12 and a quartz chamber 14 positioned therein. The wafer is supported on the holder 18 in the quartz chamber 14. When performing the rapid thermal processing, the longitudinal and transversal heating lamps 20 (such as a tungsten halogen heating lamp) are respectively heated and arranged as two rows on the top and the bottom in order to heat uniformly. A main advantage of the rapid thermal processing is that the heating and the cooling are uniformly and quickly performed. The heating increases the temperature by using the heating lamp. The cooling reduces the temperature by a high-effectively cooling apparatus. The cooling apparatus usually uses water-cooling, as shown in FIG. 1, which comprises a supply pipe 22 simultaneously connected to two chambers for providing the cooling water to two chambers. A recycle pipe connected to two chambers recycles the used cooling water. However, one pipe is simultaneously connected to two chambers. Although it will save on pipe, the amount of water and the water pressure are reduced, so that the machine is unable to optimally perform.

In view of this, the present invention provides a water-cooling apparatus for semiconductor thermal processing in order to overcome the above-mentioned disadvantages.

### SUMMARY OF THE INVENTION

The present invention provides a water-cooling apparatus for semiconductor thermal processing, which is an improved water-cooling system design to provide sufficient water pressure to the chambers.

The present invention also provides a water-cooling apparatus for semiconductor thermal processing, which prevents the machine from insufficient water pressure, resulting in increased throughput.

The present invention also provides a water-cooling apparatus for semiconductor thermal processing, which is an improved water-cooling system design without using a water pump, thereby reducing the maintenance cost.

According to an embodiment of the present invention, a water-cooling apparatus for semiconductor thermal processing is provided. Two supply pipes are connected to two chambers for providing the cooling water, and two recycle pipes are connected to two chambers for recycling the used cooling water.

These and other objectives of the present invention will become obvious to those of ordinary skill in the art after reading the following detailed description of the preferred embodiment.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic view of a conventional water-cooling apparatus;

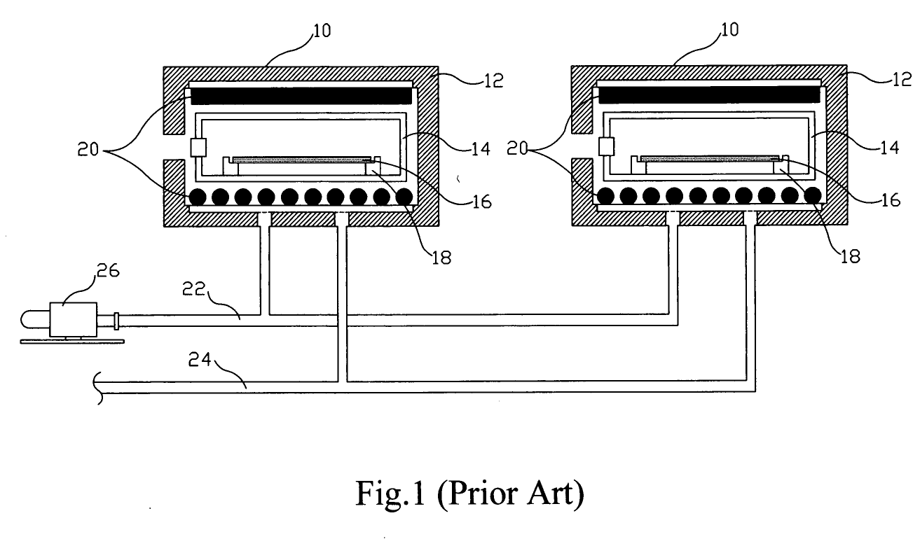

FIG. 2 is a schematic view showing the structure of a water-cooling apparatus for semiconductor thermal processing according to an embodiment of the present invention; and

FIG. 3 is a schematic view of a water-cooling apparatus for semiconductor thermal processing according to an embodiment of the present invention.

### DETAILED DESCRIPTION OF THE PREFERRED EMBODIMENTS

The present invention provides a water-cooling apparatus used in semiconductor thermal processing. Due to the architecture of pipes, one pipe is simultaneously connected to two chambers to provide the cooling water, resulting in reducing water pressure, so that the machine is unable to perform normally. If a water pump is used to increase the water pressure, the maintenance cost will be increased. The present invention provides an improved water-cooling apparatus used in semiconductor thermal processing to provide sufficient water pressure in the chamber.

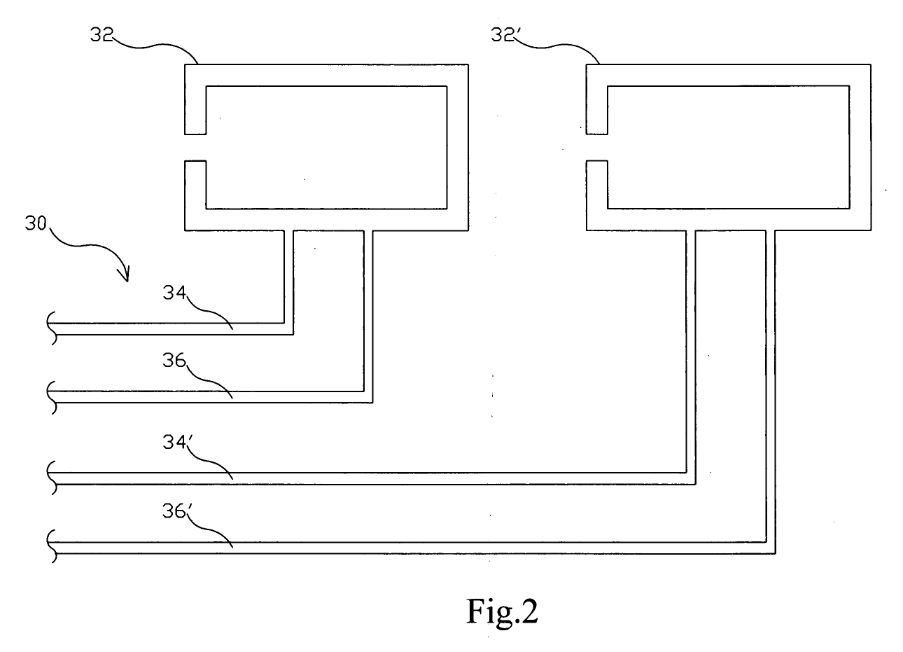

As shown in FIG. 2, two chambers 32 and 33′ for performing the thermal processing are connected to a water-cooling apparatus 30. The water-cooling apparatus 30 comprises two supply pipes 34 and 34′ respectively connected with the two chambers 32 and 33′ for respectively providing the cooling water to the two chambers 32 and 33′ in order to reduce the temperature. The water-cooling apparatus 30 also comprises two recycle pipes 36 and 36′ respectively connected with the two chambers 32 and 33′ for respectively recycling the cooling water from the two chambers by the different pipes.

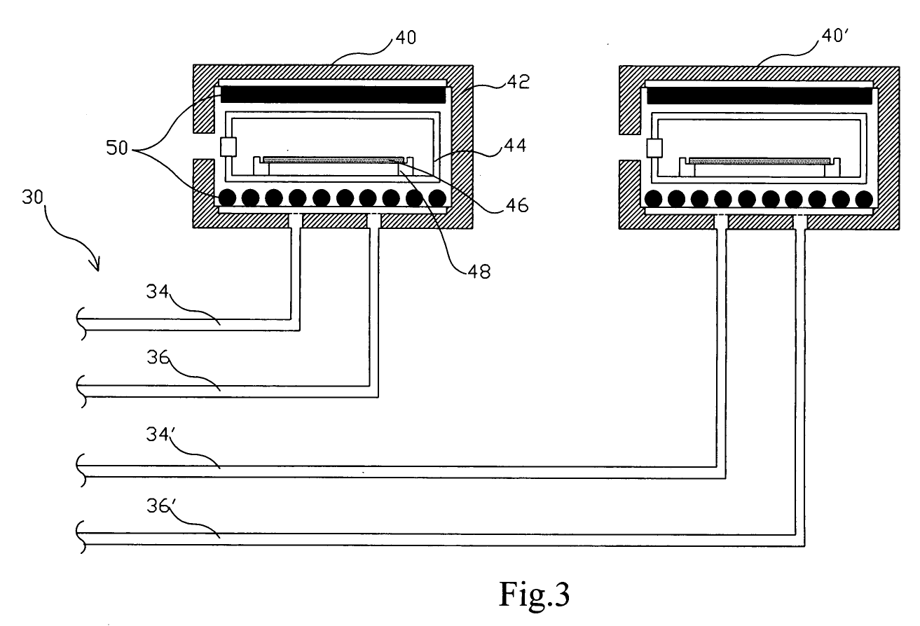

The present invention is applied in semiconductor processing consisting of various processing, such as thermal oxidation, thermal flow processing, metal silicidation processing, anneal processing, solidification processing, rapid thermal processing and so on. In order to illustrate the present invention more clearly, rapid thermal processing is given as example in an embodiment of the present invention. As shown in FIG. 3, a water-cooling apparatus 30 is connected to two chambers 40 and 40′ for performing the rapid thermal processing. These two chambers 40 and 40′ have the same structure. Therefore, one chamber 40 is illustrated as the structure. A rapid thermal chamber 40 comprises an outer chamber 42. A quartz chamber 44 is disposed in the outer chamber 42. The wafer 46 is supported on the holder 48 in the quartz chamber 44. When performing the rapid thermal processing, the longitudinal and transversal heating lamps (such as the tungsten halogen heating lamp) are respectively heated and arranged as two rows on the top and the bottom. After finished the heating of the rapid thermal process, in order to control the temperature effectively, a means of reducing the temperature is further disposed. As shown in FIG. 3, a water-cooling apparatus 30 is connected to two chambers 40 and 40′. The water-cooling apparatus 30 comprises two supply pipes 34 and 34′ and two recycle pipes 36 and 36′ for respectively connecting to the lower of two chambers 40 and 40′ to provide the cooling water to two chambers 40 and 40′ in order to reduce the temperature. In the meantime, the output ports for transporting the used cooling water is further disposed in order to continuously control the temperature. Two recycle pipes 36 and 36′ are respectively connected to the lower of two chambers 40 and 40′ for outputting the water in order to recycle the cooling water.

According to the present invention, a water-cooling apparatus provides two supply pipes and two recycle pipes respectively connected to two chambers. One chamber is connected to two pipes, one pipe is provided for supplying the cooling water, and another pipe is provided for recycling the used cooling water. This connection of the chamber and the pipes having two sets to solve the conventional disadvantages, in which one pipe simultaneously provides the cooling water to two chambers and one recycle pipe simultaneously is connected to two chambers for recycling the used cooling water, resulting in the maching being unable to perform optimally due to insufficient water pressure. The present invention provides an improved water-cooling apparatus, in which the pipes are redesigned. Each chamber respectively connects to one set of cooling water transport system.

The embodiment above is only intended to illustrate the present invention; it does not, however, to limit the present invention to the specific embodiment. Accordingly, various modifications and changes may be made without departing from the spirit and scope of the present invention as described in the following claims.

What is claimed is:

1. A water-cooling apparatus for semiconductor thermal processing, which is connected to two chambers where the semiconductor thermal processing is performed, the water-cooling apparatus comprising:
two supply pipes being respectively connected with the two chambers for respectively providing cooling water to the two chambers; and
two recycle pipes being respectively connected with the two chambers for respectively recycling cooling water from the two chambers.

2. The water-cooling apparatus for semiconductor thermal processing of claim 1, wherein the semiconductor thermal processing is rapid thermal processing.

3. The water-cooling apparatus for semiconductor thermal processing of claim 1, wherein the semiconductor thermal processing is thermal oxidation processing.

4. The water-cooling apparatus for semiconductor thermal processing of claim 1, wherein the semiconductor thermal processing is thermal flow processing.

5. The water-cooling apparatus for semiconductor thermal processing of claim 1, wherein the semiconductor thermal processing is metal silicidation processing.

6. The water-cooling apparatus for semiconductor thermal processing of claim 1, wherein the semiconductor thermal processing is anneal processing.

7. The water-cooling apparatus for semiconductor thermal processing of claim 1, wherein the semiconductor thermal processing is solidification processing.
